(19) United States
(12) Patent Application Publication
(10) Pub. No.: US 2025/0389617 A1
(43) Pub. Date: Dec. 25, 2025

(54) DISPLAY PANEL EVALUATION SYSTEM AND ELECTRONIC DEVICE

(71) Applicant: Samsung Display Co., LTD., Yongin-si (KR)

(72) Inventors: Young Min PARK, Yongin-si (KR); A Ree SONG, Yongin-si (KR); Young Keun LEE, Yongin-si (KR); Jung A CHOI, Yongin-si (KR); Hye Young HA, Yongin-si (KR)

(21) Appl. No.: 19/196,302

(22) Filed: May 1, 2025

(30) Foreign Application Priority Data
Jun. 21, 2024 (KR) 10-2024-0081149
Aug. 20, 2024 (KR) 10-2024-0111258

(51) Int. Cl. G01M 11/02; H04N 13/305; H10H 29/855

(52) U.S. Cl. CPC G01M 11/0235; G01M 11/0214; H04N 13/305; H10H 29/855

(57) ABSTRACT

A display panel evaluation system is provided including: an in-line system; a display panel assembly disposed on the in-line system; and a luminance measurer configured to capture an image output by the display panel assembly. The display panel assembly includes a display panel; an evaluation lens disposed on the display panel and configured to refract at least a portion of light output by the display panel; and a polarizing plate disposed on a rear surface of the evaluation lens. The in-line system is configured to sequentially move the display panel such that the display panel overlaps the evaluation lens in a plan view.

This application claims priority to Korean Patent Application No. 10-2024-0081149, filed on Jun. 21, 2024, and Korean Patent Application No. 10-2024-0111258, filed on Aug. 20, 2024, and all the benefits accruing therefrom under 35 U.S.C. § 119, the contents of which in their entirety are herein incorporated by reference.

### BACKGROUND

### (a) Field of the Invention

The present disclosure relates to a display panel evaluation system and electronic device.

### (b) Description of the Related Art

As information technology develops, the importance of display devices, which are a connection medium between users and information, is emerging. Accordingly, the use of display devices such as, for example, a liquid crystal display device, an organic light emitting display device, and the like has been increasing.

A stereoscopic image display device is a display device that stimulates the viewer's visual senses in the same way as an actual object and provides physical factors to stereoscopically perceive the object. For example, the stereoscopic image display device may provide different images to the viewer's left and right eyes, allowing the viewer to view the stereoscopic image through binocular parallax between the left and right eyes.

The stereoscopic image display device may include a display panel and a lens array disposed on the display panel. In this case, when the display panel is evaluated based only on the display panel, an image different from the image visually recognized by an actual user of the stereoscopic image display device may be evaluated, and the reliability of the evaluation of the display panel may be reduced.

The above information disclosed in this Background section is for enhancement of understanding of the background of the inventive concepts, and, therefore, it may contain information that does not form the prior art that is already known to a person of ordinary skill in the art.

### SUMMARY

An object of the present disclosure is to provide a display panel evaluation system that may improve the reliability of evaluation of a display panel that outputs an image corresponding to a plurality of viewpoints.

An embodiment of the present disclosure provides a display panel evaluation system including: an in-line system; a display panel assembly disposed on the in-line system; and a luminance measurer configured to measure luminance of an image output by the display panel assembly. The display panel assembly includes a display panel; an evaluation lens disposed on the display panel and configured to refract at least a portion of light output by the display panel; and a polarizing plate disposed on a rear surface of the evaluation lens. The in-line system is configured to sequentially move the display panel such that the display panel overlaps the evaluation lens in a plan view.

The rear surface of the evaluation lens may include guide portions protruding in one direction; and a mounting surface defined by the guide portions.

The polarizing plate may be disposed such that the polarizing plate is in contact with the mounting surface.

The polarizing plate may be rectangular shaped, and four sides of the polarizing plate may be in contact with the guide portions.

The evaluation lens may include a first point corresponding to a central portion of the evaluation lens and an n-th point corresponding to an outer portion of the evaluation lens, in a plan view. The evaluation lens may be configured not to refract first light which is associated with the image output by the display panel and output at the first point.

The evaluation lens may be configured to refract n-th light which is associated with the image output by the display panel and output at the n-th point.

The n-th light may be inclined at an angle of 30 degrees or more from a direction perpendicular to a plane of the display panel and be incident on the polarizing plate.

The evaluation lens may further include an i-th point disposed between the first point and the n-th point in a plan view. The evaluation lens may be configured to refract i-th light which is associated with the image output by the display panel and output at the i-th point by an amount less than an amount which the evaluation lens is configured to refract the n-th light.

The i-th light may be inclined at an angle of 15 degrees or more from a direction perpendicular to a plane of the display panel and be incident on the polarizing plate.

Respective luminances of the first light, the i-th light, and the n-th light incident on the luminance measurer may sequentially decrease.

The evaluation lens may be a convex lens or a Fresnel lens.

A distance between the luminance measurer and the evaluation lens may be 300 mm or more.

The polarizing plate and the display panel may be disposed such that the polarizing plate and the display panel are spaced apart by a predetermined interval.

The display panel may include one or more light emitting elements configured to output light of the image, and the one or more light emitting elements may be micro light emitting diodes (LEDs).

The display panel may include a first display panel disposed overlapping the evaluation lens in a plan view; and a second display panel different from the first display panel, and the in-line system may be configured not to move the first display panel and the second display panel while evaluation of the first display panel is being performed.

The in-line system may be configured to, after the evaluation of the first display panel is completed, move the second display panel in a plan view such that the second display panel overlaps the evaluation lens.

An embodiment of the present disclosure provides an electronic device, including: a processor to provide input image data; and a display device comprises a display panel to display an image based on the input image data, wherein the display panel is evaluated by a display panel evaluation system.

The display panel may comprise one or more light emitting elements configured to output light of the image, and the one or more light emitting elements are micro light emitting diodes (LEDs).

The display panel evaluation system according to the present disclosure may improve the reliability of evaluation of a display panel that outputs an image corresponding to a plurality of viewpoints.

Effects of the embodiments of the present disclosure are not limited by what is illustrated in the above, and more various effects are included in the present specification.

### BRIEF DESCRIPTION OF THE DRAWINGS

FIG. 1 is a drawing for explaining a stereoscopic image display device of a lens array type.

FIG. 2 is a drawing for explaining a relationship between a lens array and a display panel.

FIG. 3 illustrates a top plan view of a display panel of FIG. 1 according to an embodiment.

FIG. 4 illustrates a cross-sectional view of a display panel of FIG. 3 according to an embodiment.

FIG. 5 illustrates a display panel evaluation system according to a comparative example.

FIG. 6 illustrates a display panel evaluation system according to an embodiment of the present disclosure.

FIG. 7 illustrates a display panel assembly of FIG. 6 according to an embodiment.

FIG. 8 illustrates a display panel assembly of FIG. 6 according to another embodiment.

FIG. 9 illustrates paths of light output from a display panel of FIG. 7.

FIG. 10 illustrates a perspective view of a rear surface of an evaluation lens.

FIG. 11 illustrates a perspective view of an evaluation lens and a polarizing plate of FIG. 10.

FIG. 12 illustrates a top plan view of an evaluation lens and a polarizing plate according to an embodiment of the present disclosure.

FIG. 13 illustrates a graph of luminance rates measured by a luminance meter at a plurality of points of an evaluation lens.

FIG. 14 illustrates a side view of a display panel evaluation method of a display panel evaluation system according to an embodiment of the present disclosure.

FIG. 15 is a block diagram of an electronic device according to an embodiment.

FIG. 16 shows schematic views of various embodiments of an electronic device.

### DETAILED DESCRIPTION

Hereinafter, example embodiments of the present disclosure will be described in detail with reference to the accompanying drawings. The following description is intended to provide a sufficient disclosure to enable the understanding of the operation of the invention, and any other disclosure is omitted to avoid obscuring the scope of example aspects of the present disclosure. In some aspects, the inventive concept may be embodied in different forms and is not limited to the embodiments set forth herein. The embodiments described herein are provided for the purpose of describing the technical concept of the invention in sufficient detail for those skilled in the art to easily practice it.

Throughout the specification, when it is described that an element is “connected” to another element, this includes not only being “directly connected”, but also being “indirectly connected” with another device in between. The terms used herein are for the purpose of describing specific embodiments and are not intended to limit the scope of example aspects of the present disclosure. Throughout the specification, unless explicitly described to the contrary, the word “comprise” and variations such as, for example, “comprises” or “comprising” will be understood to imply the inclusion of stated elements but not the exclusion of any other elements. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms first, second, and the like may be used herein to describe various constituent elements, these constituent elements should not be limited by these terms. These terms are used to distinguish one constituent element from another. Thus, a first constituent element discussed below could be termed a second constituent element without departing from the teachings of the present disclosure.

Spatially relative terms, such as, for example, “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (for example, rotated 90 degrees or at other orientations), and, as such, the spatially relative descriptors used herein interpreted accordingly.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Various embodiments are described herein with reference to sectional illustrations that are schematic illustrations of example embodiments. As such, variations from the shapes of the illustrations as a result, for example, of manufacturing techniques and/or tolerances, are to be expected. Thus, example embodiments disclosed herein should not be construed as limited to the particular illustrated shapes of regions, but are to include deviations in shapes that result from, for instance, manufacturing. Thus, the regions illustrated in the drawings are schematic in nature and their shapes are not intended to illustrate the actual shape of a region of a device and are not intended to be limiting.

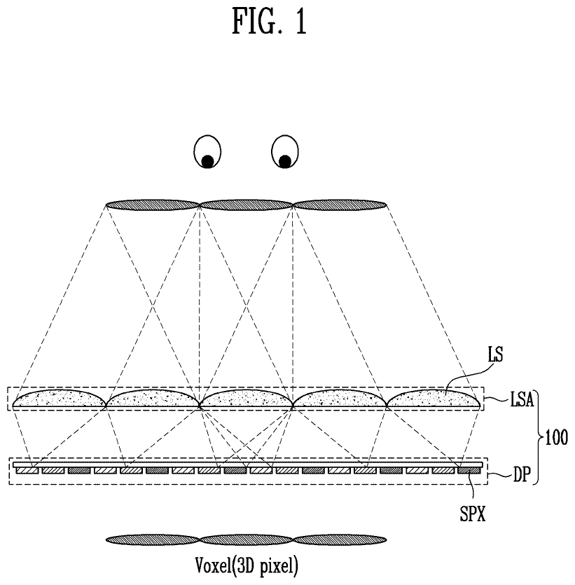

FIG. 1 is a drawing for explaining a stereoscopic image display device of a lens array type.

Referring to FIG. 1, a display device 100 may include a display panel DP and a lens array LSA.

The display panel DP may include sub-pixels SPX that emit light to display an image. In the embodiment, each of the sub-pixels SPX may output one of light of a first color (for example, red), light of a second color (for example, green), and light of a third color (for example, blue). However, this is an example, and the color of light emitted from the sub-pixels SPX is not limited thereto, and light of various colors may be outputted for full-color implementation. The display panel DP may include an organic light emitting display panel, a liquid crystal display panel, a quantum dot display panel, and the like.

The lens array LSA may be disposed on the display panel DP, and may include lenses LS that refract light incident from the sub-pixels SPX. For example, the lens array LSA may be implemented as a lenticular lens array, a micro lens array, or the like.

A light field display is a 3D display device that uses a flat display and an optical element (for example, the lens array LSA) to realize a stereoscopic image by forming a light field expressed as a vector distribution (intensity, direction) of light in space. The light field display is a display technology that may be used in various ways through combination with augmented reality (AR) technology as the light field display supports viewing a depth and a side surface of an object, enabling a more natural stereoscopic image.

The light field may be implemented in various ways. For example, a light field may be formed by a method to generate a light field in various directions using multiple projectors, a method of controlling a direction of light using a diffraction grating, a method of controlling a direction and intensity (brightness) of light according to a combination of each pixel using two or more panels, a method of controlling a direction of light using a pinhole or barrier, and a method of controlling a direction of light refraction through a lens array.

In the embodiment, as illustrated in FIG. 1, the stereoscopic image display device 100 of a lens array type may display a stereoscopic image (3D image) by forming a light field.

A series of the sub-pixels SPX may be allocated to each lens LS, and the light emitted from each of the sub-pixels SPX may be refracted by the lens LS such that the light proceeds in a specific direction (e.g., only in the specific direction) and forms a light field expressed in the intensity and direction of light. In an example in which a viewer views the display device 100 in the light field formed as described herein, the viewer may feel a stereoscopic effect of a corresponding image.

Image information in the according to the view of the viewer in the light field may be defined and processed in units of voxels. The voxel may be understood as graphic information defining a predetermined point (or pixel) of a three-dimensional space.

In this case, the resolution of a two-dimensional image may be determined by the number (for example, density) of pixels for the same area. In an example in which the number of pixels increases for the same area, the resolution may increase. That is, a display panel DP with a high pixel density may be implemented for providing a high-resolution image. Similarly, increasing the number of voxels at the same point in time through the lens array LSA may increase the resolution of the stereoscopic image.

In some embodiments, the display panel DP may be applied to an electronic device such as, for example, a smart phone, a television, a tablet PC, a mobile phone, a video phone, an e-book reader, a desktop PC, a laptop PC, a netbook computer, a workstation, a server, a PDA, a portable multimedia player (PMP), an MP3 player, a medical device, a camera, or a wearable.

In some aspects, in some embodiments, the display panel DP may be applied to a head mount display device, but is not limited to the examples described herein, and may be applied to an electronic device having a display surface applied to at least one surface.

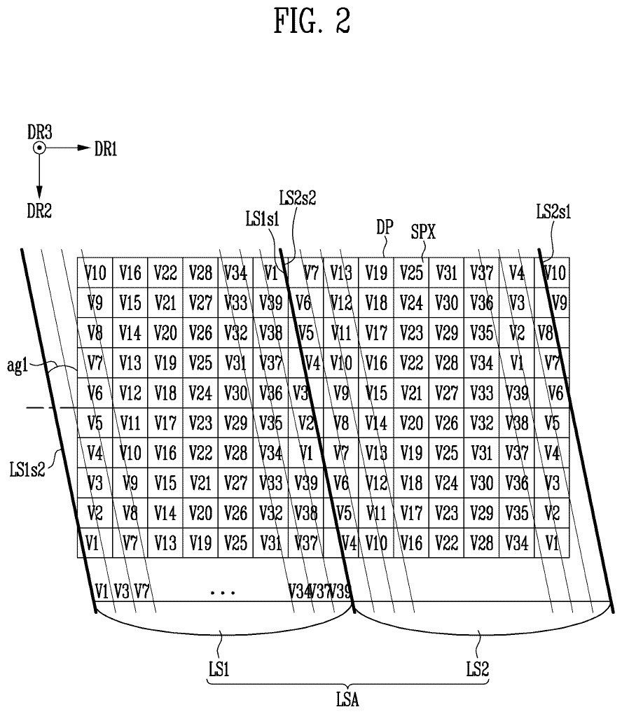

FIG. 2 is a drawing for explaining a relationship between a lens array and a display panel.

Referring to FIG. 2, the display panel DP may include sub-pixels SPX disposed in a first direction DR1 and a second direction DR2 perpendicular to the first direction DR1. The sub-pixels SPX may include light emitting surfaces in a third direction DR3 perpendicular to the first and second directions DR1 and DR2.

Each of the sub-pixels SPX may include a light emitting element configured to emit light. The light emitting element may be provided in various forms. For example, the light emitting element may be an inorganic light emitting element including an inorganic material. In some embodiments, the light emitting element may be a micro light emitting diode (LED). In some embodiments, the light emitting element may be an organic light emitting diode (OLED).

In some aspects, each of the sub-pixels SPX may be a first pixel R configured to emit red color light, a second pixel G configured to emit green color light, and a third pixel B configured to emit blue color light.

The lens array LSA may include lenses (LS1, LS2, . . . . LSm) (m is a natural number greater than or equal to 1). The lenses LS1 to LSm may be lenticular lenses.

The lenses LS1 to LSm may overlap the sub-pixels SPX in the third direction DR3. The lenses LS1 to LSm may be disposed such that the long sides of the lenses LS1 to LSm have an angle ag1 greater than 0° with respect to the second direction DR2. For example, the first lens LS1 may include a first long side LS1s1 and a second long side LS1s2 parallel to each other. In some aspects, the second lens LS2 may include a first long side LS2s1 and a second long side LS2s2 parallel to each other. The lenses LS1 to LSm may be disposed in the first direction DR1. However, in another embodiment, the angle ag1 may be 0°.

A lower surface (a surface facing the sub-pixels SPX) of each of the lenses LS1 to LSm may be divided into a plurality of view areas V1 to V39. The plurality of view areas V1 to V39 are not physically divided, but are virtual areas, and may be variously defined according to the resolution of the display panel DP, the specifications of the lenses LS1 to LSm, the number of views to be provided to the user, and the like. Each of the lenses LS1 to LSm distributes images corresponding to each of the view areas V1 to V39 in different directions (different views), such that the user may view a multi-view image in which the image varies according to the position.

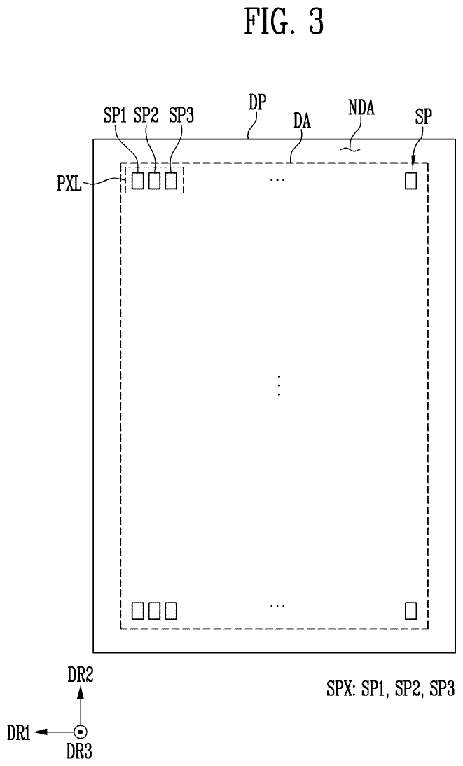

The sub-pixels SPX may overlap one or more of the plurality of view areas V1 to V39. In FIG. 2, main view areas V1 to V39 corresponding to the sub-pixels SPX are respectively displayed. In this case, the sub-pixels SPX corresponding to the same view area may display an image for the same view VW (see FIG. 3). Accordingly, as illustrated in FIG. 2, when 39 view areas V1 to V39 exist, the display panel DP may simultaneously display 39 images.

According to the embodiment, the display device 100 may display a stereoscopic image by controlling or configuring the sub-pixels SPX overlapping the view areas V1 to V20 to display a right-eye image and the sub-pixels SPX overlapping the viewpoint areas V21 to V39 to display a left-eye image. In this case, the user of the display device 100 may be positioned such that the left-eye image is visually recognized in the left eye and the right-eye image is visually recognized in the right eye.

The sub-pixels SPX may be disposed according to various structures such as, for example, an RGB stripe, a diamond PENTILE™, an S-strip, a real RGB, and a normal PENTILE™.

FIG. 3 illustrates a top plan view of a display panel of FIG. 1 according to an embodiment.

Referring to FIG. 3, the display panel DP may include a display area DA and a non-display area NDA. The display panel DP displays an image through the display area DA. The non-display area NDA is disposed around the display area DA.

The display panel DP includes sub-pixels SPX in the display area DA. The sub-pixels SPX may be arranged along the first direction DR1 and the second direction DR2 that intersects the first direction DR1. For example, the sub-pixels SPX may be arranged in a matrix format along the first direction DR1 and the second direction DR2. As another example, the sub-pixels SPX may be arranged in a zigzag form along first direction DR1 and second direction DR2. The arrangement of the sub-pixels SPX may vary in some embodiments. The first direction DR1 may be a row direction, and the second direction DR2 may be a column direction.

Two or more of the plurality of sub-pixels SPX may configure one pixel PXL. FIG. 3 illustrates that the pixel PXL includes three sub-pixels SP1 to SP3, but embodiments are not limited thereto. For example, the pixel PXL may include two sub-pixels. Hereinafter, for better understanding and ease of description, it may be assumed that the pixel PXL includes the first to third sub-pixels SP1 to SP3.

Each of the first to third sub-pixels SP1 to SP3 may generate one of various colors such as, for example, red, green, blue, cyan, magenta, and yellow. Hereinafter, for clear and brief description, it may be assumed that the first sub-pixel SP1 is configured to generate red-colored light, the second sub-pixel SP2 is configured to generate green-colored light, and the third sub-pixel SP3 is configured to generate blue-colored light.

Each of the first to third sub-pixels SP1 to SP3 may include at least one light emitting element configured to generate light. In embodiments, the light emitting elements of the first to third sub-pixels SP1 to SP3 may generate light of the same color. For example, the light emitting elements of the first to third sub-pixels SP1 to SP3 may generate blue-colored light. In other embodiments, the light emitting elements of the first to third sub-pixels SP1 to SP3 may generate light of different colors. For example, the light emitting elements of the first to third sub-pixels SP1 to SP3 may generate light of red, green, and blue colors, respectively.

As the display panel DP, a self-luminous display panel such as, for example, an LED display panel using a micro-scale or nano-scale light emitting diode as a light emitting element and an organic light emitting display panel using an organic light emitting diode as a light emitting element may be used.

A constituent element to control the sub-pixels SPX may be disposed in the non-display area NDA. Wires connected to the sub-pixels SPX, for example, gate lines, data lines, and pixel control lines may be disposed in the non-display area NDA.

In embodiments, the display area DA may have various shapes. The display area DA may have a closed-loop shape including sides of a straight line and/or a curved line. For example, the display area DA may have shapes such as, for example, a polygonal shape, a circular shape, a semicircular, and an elliptical shape.

In embodiments, the display panel DP may have a flat display surface. In other embodiments, the display panel DP may have a display surface that is at least partially round. In embodiments, the display panel DP may be bendable, foldable, or rollable. In these cases, the display panel DP and/or the substrate of the display panel DP may include materials with flexible properties.

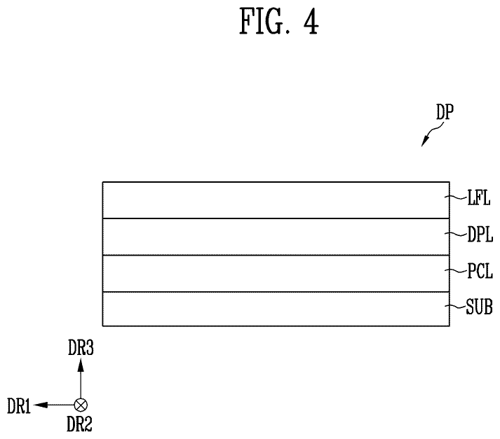

FIG. 4 illustrates a cross-sectional view of a display panel of FIG. 3 according to an embodiment.

Referring to FIG. 4, the display panel DP may include a substrate SUB, and a pixel circuit layer PCL, a display element layer DPL, and a light functional layer LFL, which are sequentially stacked on the substrate SUB in a third direction DR3 crossing the first and second directions DR1 and DR2.

The substrate SUB may be formed of an insulating material such as, for example, glass or a resin. For example, the substrate SUB may include a glass substrate. As another example, the substrate SUB may include a polyimide (PI) substrate. As yet another example, the substrate SUB may include a silicon wafer substrate formed using a semiconductor process.

In embodiments, the substrate SUB may be formed of a flexible material to be bendable or foldable, and may have a single-layered structure or a multi-layered structure. For example, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL is disposed on the substrate SUB. The pixel circuit layer PCL may include insulating layers and semiconductor patterns and conductive patterns disposed between the insulating layers. The conductive patterns of the pixel circuit layer PCL may function as circuit elements, wires, and the like.

The circuit elements of the pixel circuit layer PCL may include the sub-pixel circuit of each of the sub-pixels SPX of FIG. 3. In other words, the circuit elements of the pixel circuit layer PCL may be provided as transistors and one or more capacitors of the sub-pixel circuit.

The wires of the pixel circuit layer PCL may include wires connected to the sub-pixels SPX. The wires of the pixel circuit layer PCL may include various signal lines and/or voltage lines supportive of providing signals and/or voltages for driving the display element layer DPL.

The display element layer DPL is disposed on the pixel circuit layer PCL. The display panel layer DPL may include light emitting elements of the sub-pixels SPX.

The light functional layer LFL may be disposed on the display element layer DPL. The light functional layer LFL may include light conversion patterns having color conversion particles and/or scattering particles. For example, the color conversion particles may include quantum dots. The quantum dots may change the wavelength (or color) of light emitted from the display element layer DPL. The light functional layer LFL may further include light scattering patterns with scattering particles. In embodiments, the light conversion patterns and the light scattering patterns may be omitted.

The light functional layer LFL may further include a color filter layer including color filters. The color filter may selectively transmit light of a specific wavelength (or a specific color). In embodiments, the color filter layer may be omitted.

A window for protecting an exposed surface (or upper surface) of the display panel DP may be provided on the light functional layer LFL. The window may protect the display panel DP from external impact. The window may be coupled to the light functional layer LFL through an optically transparent adhesive (bonding) member. The window may have a multi-layered structure selected from a glass substrate, a plastic film, and a plastic substrate. The multi-layered structure may be formed through a continuous process or an adhesive process using an adhesive layer. All or a portion of the window may be flexible.

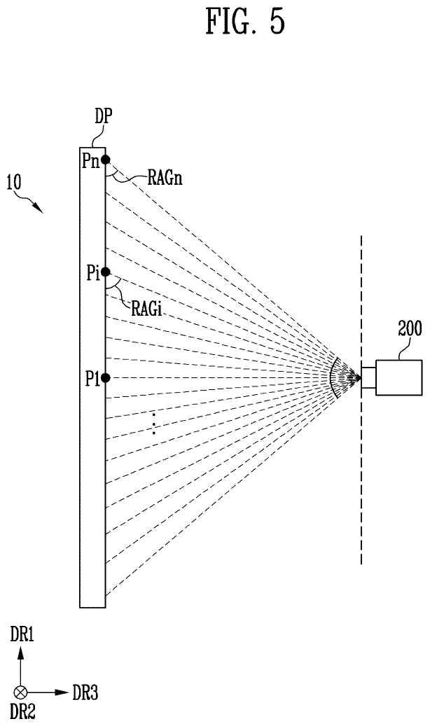

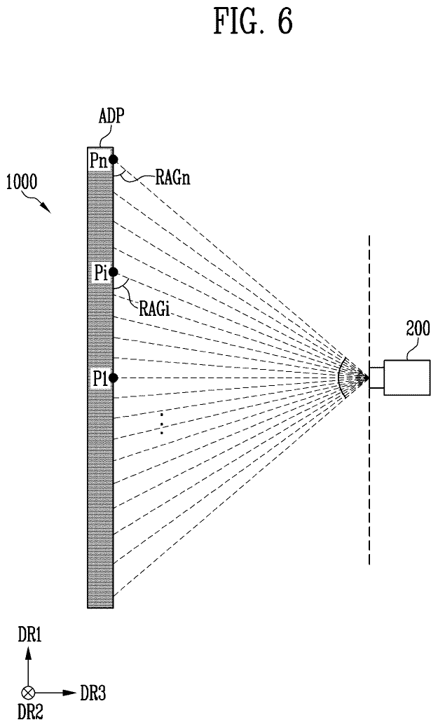

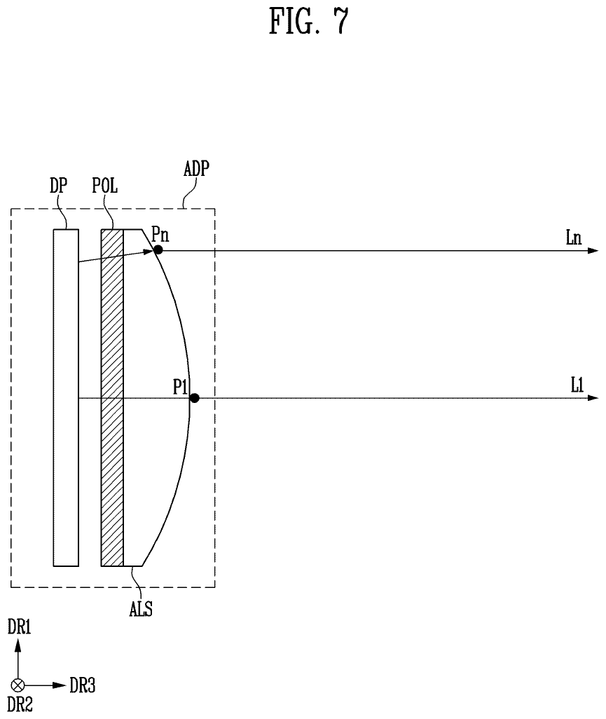

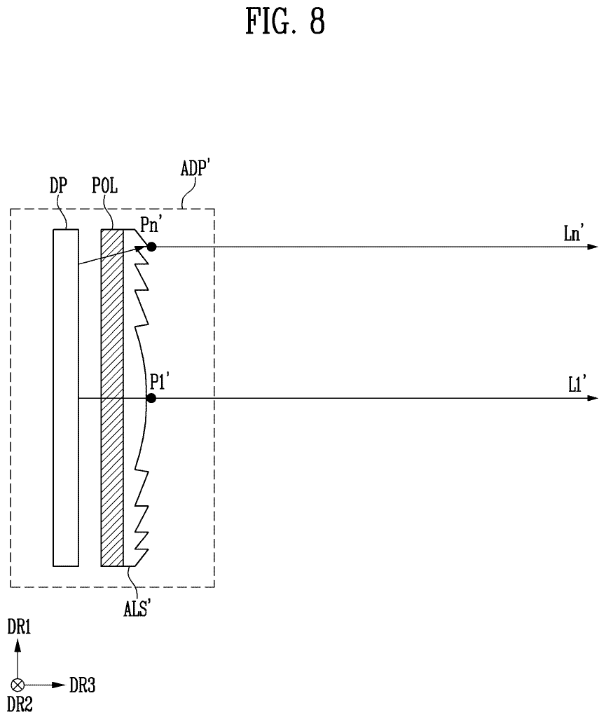

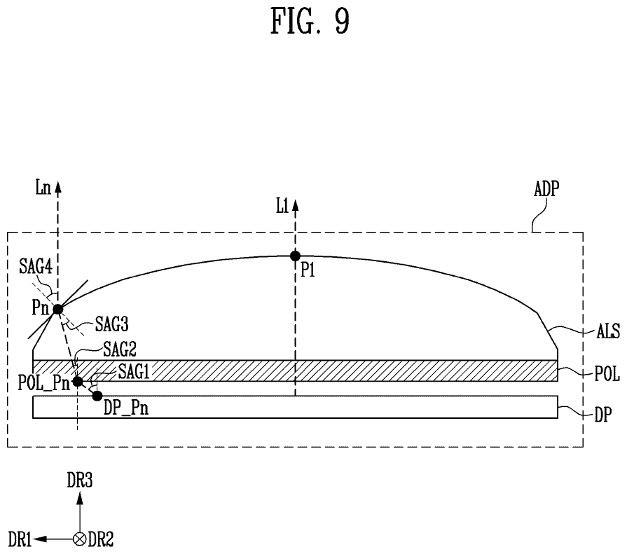

FIG. 5 illustrates a display panel evaluation system according to a comparative example. FIG. 6 illustrates a display panel evaluation system according to an embodiment of the present disclosure. FIG. 7 illustrates a display panel assembly of FIG. 6 according to an embodiment. FIG. 8 illustrates a display panel assembly of FIG. 6 according to another embodiment. FIG. 9 illustrates paths of light output from a display panel of FIG. 7.

Referring to FIG. 5, a display panel evaluation system 10 according to a comparative example may include a display panel DP and a luminance measurer 200. The display panel DP of FIG. 5 may be described similarly to the display panel DP of FIG. 1. Hereinafter, redundant descriptions thereof will be omitted.

The luminance measurer 200 may include a camera configured to capture a multi-view image displayed by the display panel DP. For example, the camera may capture stereoscopic images output by the display panel DP. The luminance measurer 200 may measure the luminance of light output at various points on the display panel DP based on the captured images.

The camera may be a spectroradiometer or a multi-spectral camera, but is not limited thereto. For example, the camera may be any device capable of measuring the luminance of a multi-view image displayed by the display panel DP in support of example embodiments described herein.

The display panel DP may output a multi-view image. Light of an image output by the display panel DP at the first point P1 may be incident on the luminance measurer 200 from the display panel DP. Light of an image output by the display panel DP at the i-th point Pi may be incident on the luminance measurer 200 with the i-th output angle RAGi from the display panel DP. In other words, the light of the image output by the display panel DP at the i-th point Pi may travel straight to the luminance measurer 200 with the i-th output angle RAGi without being refracted. Light of an image output by the display panel DP at the n-th point Pn may be incident on the luminance measurer 200 with the n-th output angle RAGn from the display panel DP.

The first point P1 may be positioned at the center of the upper surface of the display panel DP. The n-th point Pn may be positioned at one end of the upper surface of the display panel DP. For example, the n-th point Pn may be positioned at one end in the first direction DR1 on the upper surface of the display panel DP. The i-th point Pi may be disposed between the first point P1 and the n-th point Pn in a plan view. According to the embodiment, a plurality of points, each of which outputs an image, may be disposed between the first point P1 and the nth point Pn.

In FIG. 5, a display panel evaluation system 10 that evaluates the performance of the display panel DP before the display device 100 of FIG. 1 is completely manufactured will be described. In other words, unlike the display device 100, the display panel DP may be evaluated by the display panel evaluation system 10 in a state in which the lens array LSA is not disposed. Accordingly, the luminance of the image visually recognized by the actual user of the display device 100 and the luminance measured by the display panel evaluation system 10 may be different. For example, the luminance of light output at the n-th point Pn in FIG. 5 may be different from the luminance of light recognized by the user of the actual display device 100. That is, according to the comparative example, the reliability of the evaluation of the display panel DP may be reduced.

Referring to FIG. 6, a display panel evaluation system 1000 according to an embodiment of the present disclosure may include a display panel assembly ADP and a luminance measurer 200. The luminance measurer 200 of FIG. 6 may be described similarly to the luminance measurer 200 of FIG. 5. Hereinafter, redundant descriptions thereof will be omitted.

In FIG. 6 to FIG. 8, the display panel evaluation system 1000 using the display panel assembly ADP is illustrated in order to exclude the risk of lowering the reliability of the evaluation of the display panel DP described herein. In other words, the display panel evaluation system 1000 in which a polarizing plate POL and an evaluation lens ALS are disposed on the display panel DP is illustrated.

Referring to FIG. 6 to FIG. 8, the display panel assembly ADP may include the display panel DP, the polarizing plate POL, and the evaluation lens ALS.

The polarizing plate POL may be disposed on the display panel DP. For example, the polarizing plate POL may be spaced apart from the display panel DP by a predetermined distance in the third direction DR3.

The polarizing plate POL may polarize light incident from the display panel DP. For example, the polarizing plate POL is a film that may separate vertical or horizontal polarization of incident light and pass or block it, and may include a poly ethylene terephthalate (PET) film or a tri-acetyl cellulose (TAC) film. However, this is an example, and the present disclosure not limited thereto.

The evaluation lens ALS may be disposed on the upper surface of the polarizing plate POL. According to the embodiment, referring to FIG. 7, the evaluation lens ALS may be a convex lens. For example, the evaluation lens ALS may have a convex shape in the third direction DR3. According to another embodiment, referring to FIG. 8, the evaluation lens ALS may be a Fresnel lens. Hereinafter, for better understanding and ease of description, the evaluation lens ALS is described as a convex lens, but is not limited thereto.

Referring to FIG. 6 to FIG. 8, the first light L1 and the n-th light Ln may be output by the display panel assembly ADP. For example, the first light L1 that travels straight in the third direction DR3 may be output from the first point P1 of the display panel assembly ADP. In some aspects, the n-th light Ln that travels straight in the third direction DR3 may be output from the n-th point Pn of the display panel assembly ADP.

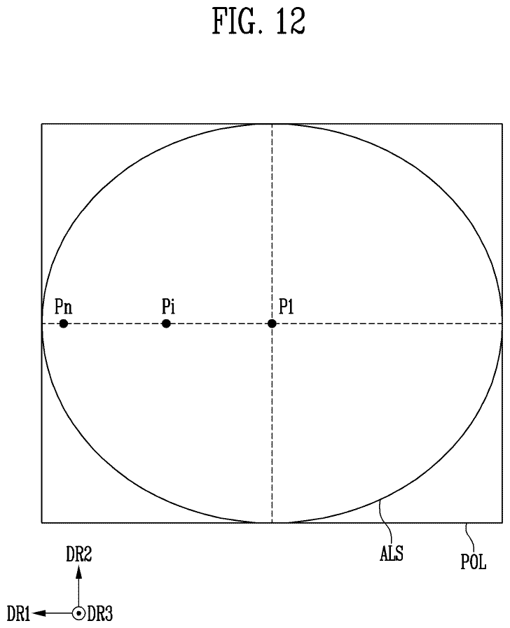

Referring to FIG. 9, the n-th light Ln may be light outputted from the display panel DP and refracted by the polarizing plate POL and the evaluation lens ALS. For example, the n-th light Ln may travel straight to the polarizing plate POL with the first incident angle SAG1 from the third direction DR3 at the (n_1)-th point DP_Pn. Thereafter, the n-th light Ln may travel straight to the n-th point Pn with the second incident angle SAG2 from the third direction DR3 at the (n_2)-th point POL_Pn. In this case, the n-th light Ln may be incident at the third incident angle SAG3 with respect to the interface of the evaluation lens ALS. Thereafter, the n-th light Ln may be output in the third direction DR3 with the fourth incident angle SAG4 with respect to the interface of the evaluation lens ALS. The i-th point Pi (see FIG. 6 and FIG. 12) may also be described similarly. For example, at the (i_1)-th point, the n-th light Ln may travel straight to the polarizing plate POL with the first incident angle from the third direction DR3. In this case, the first incident angle at the (i_1)-th point may be smaller than the first incident angle SAG1 at the (n_1)-th point. In some embodiments, the first incident angle at the (i_1)-th point may be 15 degrees or more.

The first light L1′ and the n-th light Ln′ of FIG. 8 may be described similarly to the first light L1 and the n-th light Ln of FIG. 7.

The first incident angle SAG1 may be greater than the second incident angle SAG2. The second incident angle SAG2 may be smaller than the third incident angle SAG3. The third incident angle SAG3 may be smaller than the fourth incident angle SAG4. In some embodiments, the first incident angle SAG1 may be 30 degrees or more.

Some of the light output by the display panel assembly ADP may be refracted light. For example, the first light L1 output by the display panel DP may be light that is not refracted. In some embodiments, the n-th light Ln output by the display panel DP may be light refracted in a direction opposite to the first direction DR1 by the polarizing plate POL and the evaluation lens ALS.

According to the embodiment of the present disclosure, the display panel evaluation system 1000 may evaluate the display panel DP (or the display panel assembly ADP) based on an image that is substantially the same as an image recognized by an actual user of the display device 100. For example, the user of the display device 100 may recognize light output by the display panel DP and refracted by the lens array LSA. However, according to the comparative example of FIG. 5, the light output from the n-th point Pn of the display panel DP may be light that is not refracted. In other words, the light output from the n-th point Pn by the display panel DP of FIG. 5 may be light that is not refracted and travels straight to the luminance measurer 200. That is, the display panel evaluation system 1000 according to the embodiment of the present disclosure may evaluate substantially the same light as the light of the image output by the display device 100 to the actual user of the display device 100 through the n-th point Pn. In other words, the light output by the display panel assembly ADP at the n-th point Pn and incident on the luminance measurer 200 may be substantially the same as the light of the image output to the actual user of the display device 100. Accordingly, the light visually recognized by the user of the display device 100 and the light incident on the luminance measurer 200 of the display panel evaluation system 1000 may be substantially the same, and reliable evaluation of the display panel DP may be performed.

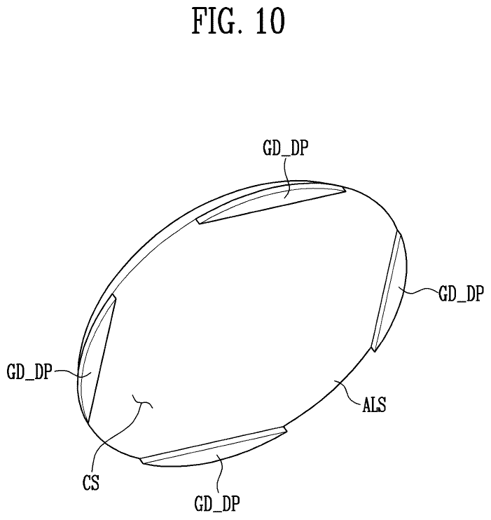

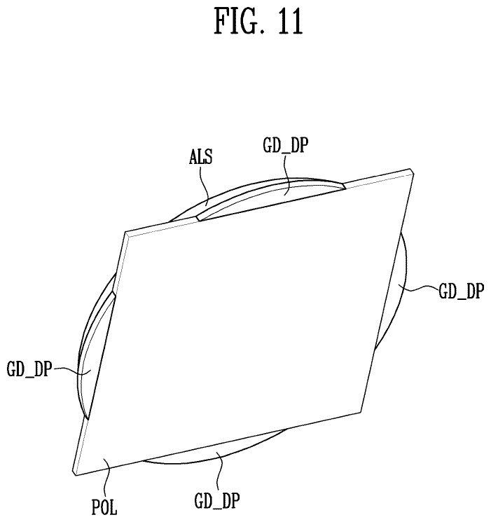

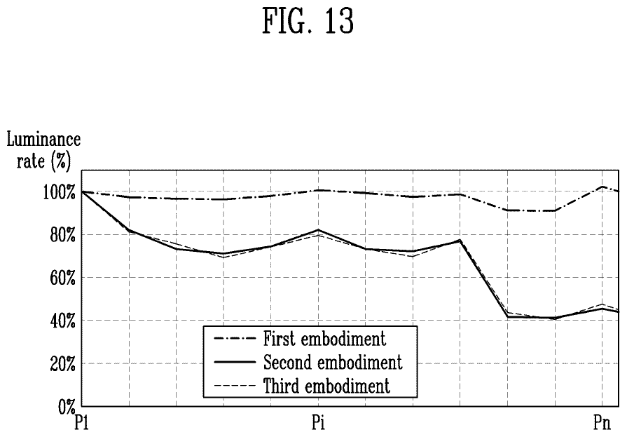

FIG. 10 illustrates a perspective view of a rear surface of an evaluation lens. FIG. 11 illustrates a perspective view of an evaluation lens and a polarizing plate of FIG. 10. FIG. 12 illustrates a top plan view of an evaluation lens and a polarizing plate according to an embodiment of the present disclosure. FIG. 13 illustrates a graph of luminance rates measured by a luminance meter at a plurality of points of an evaluation lens.

Referring to FIG. 10, the evaluation lens ALS may include a plurality of guide portions GD_DP. For example, a plurality of guide portions GD_DP protruding in one direction may be disposed on the rear surface of the evaluation lens ALS. According to the embodiment, as illustrated in FIG. 10, 4 guide portions GD_DP may be included. However, embodiments of the present disclosure are not limited thereto.

The evaluation lens ALS may include a mounting surface CS disposed on the rear surface of the evaluation lens ALS. The mounting surface CS may be a surface defined by the plurality of guide portions GD_DP. In other words, the mounting surface CS may be a surface having a circular shape in a plan view and surrounded by the guide portions GD_DP.

Referring to FIG. 10 and FIG. 11, the polarizing plate POL may be disposed on the rear surface of the evaluation lens ALS. For example, the polarizing plate POL may be disposed on the mounting surface CS while contacting the guide portions GD_DP.

Referring to FIG. 10 to FIG. 12, in a plan view, the evaluation lens ALS may have a circular shape. The polarizing plate POL may have a quadrangular shape. In a plan view, the edge of the polarizing plate POL may not overlap the evaluation lens ALS. For example, the edge of the polarizing plate POL may be disposed between one of the guide portions GD_DP and another one of the guide portions GD_DP.

The first point P1 may be disposed at the center of the evaluation lens ALS. The n-th point Pn may be disposed on the side surface of the evaluation lens ALS. For example, the n-th point Pn may be disposed adjacent to one end of the evaluation lens ALS in the first direction DR1. The i-th point Pi may be disposed between the first point P1 and the n-th point Pn. Although three points are illustrated in FIG. 12, this is an example, and the present disclosure not limited thereto.

FIG. 13 illustrates a graph of the luminance rate of light output from a plurality of points on the interface of the evaluation lens ALS according to the first to third embodiments. The first embodiment may be an embodiment in which light of an image output by the display panel DP is measured using the luminance measurer 200 (see FIG. 6). The second embodiment may be an embodiment in which light of an image output from the display device 100 (see FIG. 1) having the lens array LSA (see FIG. 1) disposed on the display panel DP is measured using the luminance measurer 200 (also referred to herein as a luminance meter). The third embodiment may be an embodiment in which light of an image output by the display panel assembly ADP in which the polarizing plate POL and the evaluation lens ALS are disposed is measured using the luminance measurer 200.

According to the first embodiment, the luminance rate from the first point P1 to the n-th point Pn may be substantially the same. In other words, the luminance rate may not significantly change depending on the position of the display panel DP. For example, the luminance rate at the first point P1, the luminance rate at the i-th point Pi, and the luminance rate at the n-th point Pn may be 100%.

According to the second embodiment, the luminance rate may decrease from the center to the periphery of the display panel DP (or, the lens array LSA overlapping the display panel DP). For example, the luminance rate at the first point P1 may be 100%. The luminance rate at the i-th point i Pi may be 80%. The luminance rate at the n-th point Pn may be 40%. Expressed another way, respective luminances of the first light L1, an i-th light incident on the luminance measurer 200, and the n-th light Ln incident on the luminance measurer sequentially decreases.

In other words, the degree to which light of an image is refracted by the lens array LSA may increase as the light proceeds toward the outside of the display panel DP, and the luminance rate may also decrease. Expressed another way, the degree to which light of an image is refracted by the lens array LSA may increase in a direction toward the outside of the display panel DP, and the luminance rate may decrease in the direction toward the outside of the display panel DP.

Features described with reference to the third embodiment may include aspects of the second embodiment. For example, the luminance rate graph according to the third embodiment, may correspond to the luminance rate graph of the second embodiment. For example, the luminance rate may decrease from the center to the periphery of the display panel DP (or evaluation lens ALS) of the third embodiment. According to the third embodiment, by disposing the polarizing plate POL and the evaluation lens ALS on the display panel DP, an image substantially identical to an image actually viewed by the user of the display device 100 (see FIG. 1) may be output. That is, according to the display panel evaluation system 1000, the reliability of the evaluation of the display device 100 (or the display panel DP) may be improved.

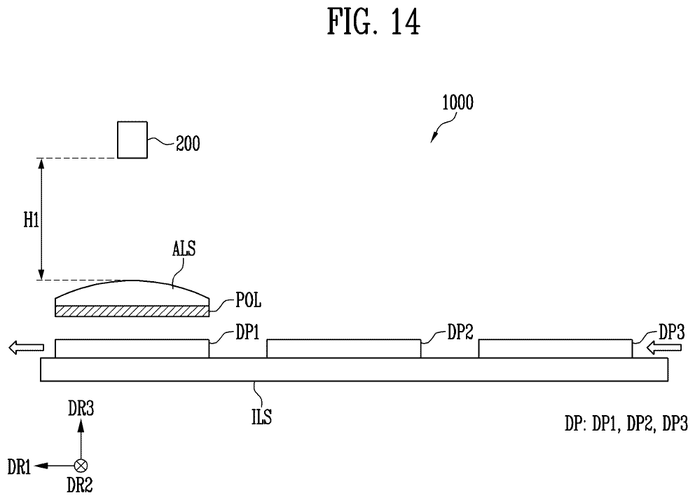

FIG. 14 illustrates a side view of a display panel evaluation method of a display panel evaluation system according to an embodiment of the present disclosure.

Referring to FIG. 14, the display panel evaluation system 1000 may include an in-line system ILS, a display panel DP, a polarizing plate POL, an evaluation lens ALS, and a luminance measurer 200. The display panel DP, the polarizing plate POL, the evaluation lens ALS, and the luminance measurer 200 of FIG. 14 may be described similarly to the display panel DP, the polarizing plate POL, the evaluation lens ALS, and the luminance measurer 200 of FIG. 6 and FIG. 7.

Hereinafter, redundant descriptions thereof will be omitted.

The in-line system ILS may be a base surface on which the display panels DP are mounted. For example, the first to third display panels DP1 to DP3 may be disposed in the in-line system ILS.

The luminance measurer 200, the polarizing plate POL, and

the evaluation lens ALS may be maintained in a fixed state. For example, the polarizing plate POL and the evaluation lens ALS may be fixed while being disposed on the display panels DP. In this case, the luminance measurer 200 may be disposed parallel to the polarizing plate POL and the evaluation lens ALS in the third direction DR3.

The in-line system ILS may sequentially move the display panels DP. For example, the in-line system ILS may move the first to third display panels DP1 to DP3 in the first direction DR1. In other words, the in-line system ILS may sequentially move the display panels DP such that the display panels correspond to the evaluation lens ALS (or the polarizing plate POL). Accordingly, the display panel evaluation system 1000 may sequentially evaluate the first to third display panels DP1 to DP3 through the luminance measurer 200.

The distance between the luminance measurer 200 and the evaluation lens ALS may be a first length H1. For example, the distance between the luminance measurer 200 and the uppermost end of the evaluation lens ALS in the third direction DR3 may be the first length H1. According to the embodiment, the first length H1 may be 300 mm or more. However, this is an example, and the present disclosure not limited thereto.

A display device according to an embodiment is applicable to various types of electronic devices. In an embodiment, an electronic device includes the above-described display device and may further include other modules or devices having additional functions in addition to the display device.

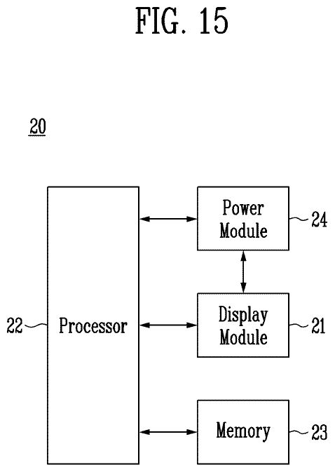

FIG. 15 is a block diagram of an electronic device according to an embodiment. Referring to FIG. 15, the electronic device 20 may include a display module 21, a processor 22, a memory 23, and a power module 24.

The processor 22 may include at least one of a central processing unit (CPU), an application processor (AP), a graphic processing unit (GPU), a communication processor (CP), an image signal processor (ISP), and a controller.

The memory 23 may store data and/or information used to operate the processor 22 or the display module 21. When the processor 22 executes an application stored in the memory 23, image data signals and/or input control signals may be transferred to the display module 21. The display module 21 may process the provided signals and output image information on a display screen. The display module 21 which is illustrated in FIG. 1, may include aspects of and be described identically to the display device 100 which is illustrated in FIG. 1. Hereinafter, overlapping descriptions will be omitted.

The power module 24 may include a power supply module, such as a power adapter or a battery device, and a power conversion module. The power conversion module converts power supplied by the power supply module and generates power to operate the electronic device 20.

At least one of the above-described components of the electronic device 20 may be included in the display device according to embodiments as described above. In addition, in terms of functionality, some of the individual modules included in one module may be included in the display device and others may be provided separately from the display device. For example, the display module 21 is included in the display device 100 which is illustrated in FIG. 1, whereas the processor 22, the memory 23, and the power module 24 are not included in the display device and are instead provided separately in the electronic device 10.

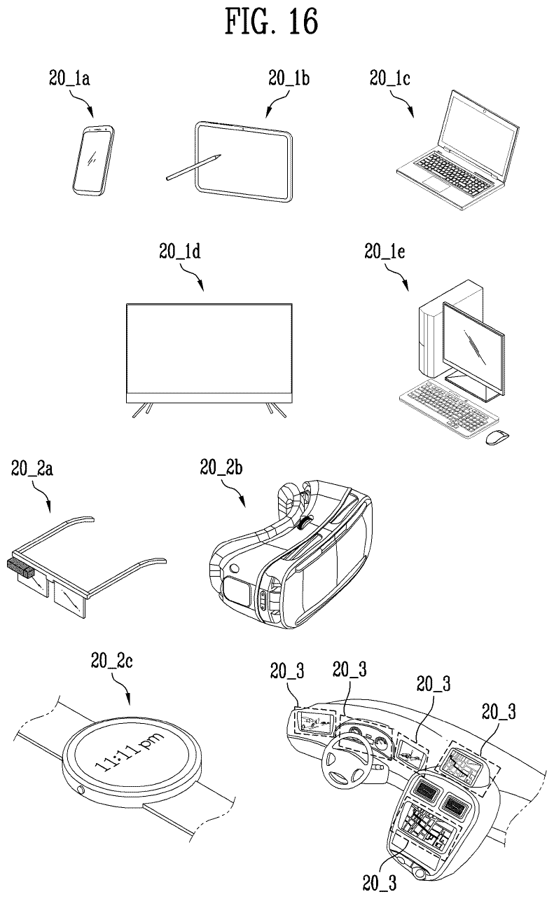

FIG. 16 shows schematic views of various embodiments of an electronic device.

Referring to FIG. 16, various types of electronic devices to which embodiments of a display device are applied may include an electronic device to display images such as a smartphone 20_1a, a tablet PC 20_1b, a laptop computer 20_1c, a television (TV) 20_1d, and a desktop monitor 20_1e, a wearable electronic device including a display module such as smart glasses 20_2a, a head-mounted display (HMD) 20_2b, and a smart watch 20_2c, and an automotive electronic device 20_3 including a display module such as a center information display (CID) disposed at the instrument cluster, the center fascia, and the dashboard of a vehicle, and a room mirror display.

Although certain embodiments and implementations have been described herein, other embodiments and modifications will be apparent from this description. Accordingly, the inventive concept is not limited to the embodiments, but rather to the broader scope of the presented claims and various obvious modifications and equivalent arrangements.

What is claimed is:

1. A display panel evaluation system comprising:
an in-line system;
a display panel assembly disposed on the in-line system; and
a luminance measurer configured to measure luminance of an image output by the display panel assembly,
wherein the display panel assembly comprises:
a display panel;
an evaluation lens disposed on the display panel and configured to refract at least a portion of light output by the display panel; and
a polarizing plate disposed on a rear surface of the evaluation lens, and
the in-line system is configured to sequentially move the display panel such that the display panel overlaps the evaluation lens in a plan view.

2. The display panel evaluation system of claim 1, wherein the rear surface of the evaluation lens comprises:
guide portions protruding in one direction; and
a mounting surface defined by the guide portions.

3. The display panel evaluation system of claim 2, wherein the polarizing plate is disposed such that the polarizing plate is in contact with the mounting surface.

4. The display panel evaluation system of claim 3, wherein:
the polarizing plate is rectangular shaped, and
four sides of the polarizing plate are in contact with the guide portions.

5. The display panel evaluation system of claim 1, wherein:
the evaluation lens comprises a first point corresponding to a central portion of the evaluation lens and an n-th point corresponding to an outer portion of the evaluation lens, in a plan view, and
the evaluation lens is configured not to refract first light which is associated with the image output by the display panel and output at the first point.

6. The display panel evaluation system of claim 5, wherein the evaluation lens is configured to refract n-th light which is associated with the image output by the display panel and output at the n-th point.

7. The display panel evaluation system of claim 6, wherein the n-th light is inclined at an angle of 30 degrees or more from a direction perpendicular to a plane of the display panel and is incident on the polarizing plate.

8. The display panel evaluation system of claim 7, wherein:
the evaluation lens further comprises an i-th point disposed between the first point and the n-th point in a plan view, and
the evaluation lens is configured to refract i-th light which is associated with the image output by the display panel and output at the i-th point by an amount less than an amount which the evaluation lens is configured to refract the n-th light.

9. The display panel evaluation system of claim 8, wherein the i-th light is inclined at an angle of 15 degrees or more from a direction perpendicular to a plane of the display panel and is incident on the polarizing plate.

10. The display panel evaluation system of claim 9, wherein respective luminances of the first light, the i-th light, and the n-th light incident on the luminance measurer sequentially decreases.

11. The display panel evaluation system of claim 1, wherein the evaluation lens is a convex lens or a Fresnel lens.

12. The display panel evaluation system of claim 1, wherein a distance between the luminance measurer and the evaluation lens is 300 mm or more.

13. The display panel evaluation system of claim 1, wherein the polarizing plate and the display panel are disposed such that the polarizing plate and the display panel are spaced apart by a predetermined interval.

14. The display panel evaluation system of claim 1, wherein:
the display panel comprises one or more light emitting elements configured to output light of the image, and
the one or more light emitting elements are micro light emitting diodes (LEDs).

15. The display panel evaluation system of claim 1, wherein:
the display panel comprises:
a first display panel disposed overlapping the evaluation lens in a plan view; and
a second display panel different from the first display panel, and
the in-line system is configured not to move the first display panel and the second display panel while evaluation of the first display panel is being performed.

16. The display panel evaluation system of claim 15, wherein the in-line system is configured to, after the evaluation of the first display panel is completed, move the second display panel in a plan view such that the second display panel overlaps the evaluation lens.

17. An electronic device, comprising:
a processor to provide input image data; and
a display device comprises a display panel to display an image based on the input image data,
wherein the display panel is evaluated by a display panel evaluation system of claim 1.

18. The electronic device of claim 17, wherein:
the display panel comprises one or more light emitting elements configured to output light of the image, and
the one or more light emitting elements are micro light emitting diodes (LEDs).
